(19) United States
(12) Patent Application Publication
(10) Pub. No.: US 2026/0164671 A1
(43) Pub. Date: Jun. 11, 2026

(54) SEMICONDUCTOR DEVICE AND METHOD FOR FABRICATING THE SAME

(71) Applicant: SK hynix Inc., Gyeonggi-do (KR)

(72) Inventors: Jeong Myeong KIM, Gyeonggi-do (KR); Cha Deok DONG, Gyeonggi-do (KR); Keo Rock CHOI, Gyeonggi-do (KR)

(21) Appl. No.: 19/242,989

(22) Filed: Jun. 19, 2025

(30) Foreign Application Priority Data
Dec. 10, 2024 (KR) 10-2024-0182404

(51) Int. Cl. H10B 61/00

(52) U.S. Cl. CPC H10B 61/10

(57) ABSTRACT

A semiconductor device and a method for fabricating the semiconductor device are provided. The semiconductor device includes a plurality of memory cells, wherein each of the memory cells includes a memory layer; a selector layer configured to select the memory layer and formed in a portion of the memory layer, wherein the selector layer includes an amorphous silicon layer having a dopant including a Group-13 element and a Group-15 element of a periodic table; and an oxide layer disposed over the selector layer and formed by oxidizing at least a portion of the selector layer.

### CROSS-REFERENCE TO RELATED APPLICATIONS

The present application claims priority under 35 U.S. C 119(a) to Korean Patent Application No. 10-2024-0182404, filed on Dec. 10, 2024, in the Korean Intellectual Property Office, which is incorporated herein by reference in its entirety.

### BACKGROUND

### 1. Field

Exemplary embodiments of the present disclosure relate to a semiconductor technology, and more particularly, to a semiconductor device including a memory cell having a selector, and a method for fabricating the semiconductor device.

### 2. Description of the Related Art

Recent demands for miniaturization, low power consumption, high performance, and diversification of electronic devices require semiconductor devices capable of storing data in diverse electronic devices, such as computers, portable communication devices and the like. Researchers and the industry have been studying to develop such semiconductor devices. These semiconductor devices include those capable of storing data by using the characteristics of switching between different resistance states according to the applied voltage or current, such as a Resistive Random Access Memory (RRAM), a Phase-change Random Access Memory (PRAM), a Ferroelectric Random Access Memory (FRAM), a Magnetic Random Access Memory (MRAM), an E-fuse and the like.

### SUMMARY

Embodiments of the present disclosure are directed to a semiconductor device with improved selector characteristics of a memory cell, and a method for fabricating the semiconductor device.

In accordance with an embodiment of the present disclosure, a semiconductor device includes: a plurality of memory cells, wherein each of the memory cells includes a memory layer; a selector layer configured to select the memory layer and formed in a portion of the memory layer, wherein the selector layer includes an amorphous silicon layer having a dopant including a Group-13 element and a Group-15 element of a periodic table; and an oxide layer disposed over the selector layer and formed by oxidizing at least a portion of the selector layer.

In accordance with another embodiment of the present disclosure, a method for fabricating a semiconductor device including a selector layer in a memory cell among a plurality of arrayed memory cells to control electrical access to the memory cell includes: forming, over a substrate, an amorphous silicon layer having at least one dopant as the selector layer; oxidizing at least a portion of the selector layer, by performing an oxygen plasma treatment, to form an oxide layer over the selector layer; and performing a heat treatment at a temperature less than or equal to a temperature where the amorphous silicon layer is crystallized.

### BRIEF DESCRIPTION OF THE DRAWINGS

FIGS. 1A and 1B illustrate a semiconductor device in accordance with an embodiment of the present disclosure.

FIG. 2 is a cross-sectional view illustrating a structure of a selector unit in accordance with an embodiment of the present disclosure.

FIG. 3 illustrates an operation of the selector unit shown in FIG. 2 in accordance with an embodiment of the present disclosure.

FIGS. 4A to 4H are cross-sectional views illustrating a semiconductor device and a method for fabricating the same in accordance with an embodiment of the present disclosure.

### DETAILED DESCRIPTION

Hereinafter, the various embodiments of the present disclosure will be described in detail with reference to the attached drawings.

Exemplary embodiments of the present disclosure will be described below in detail with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout the disclosure, like reference numerals refer to like parts throughout the various figures and embodiments of the present disclosure.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

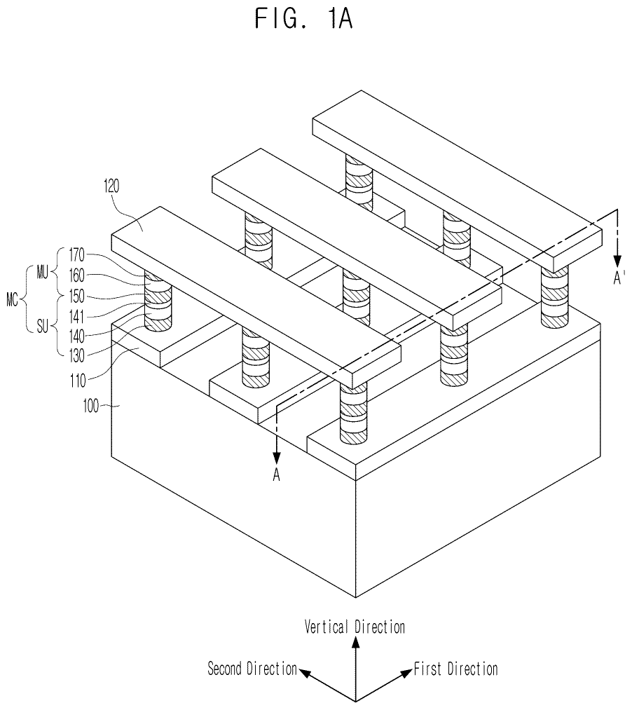

FIGS. 1A and 1B illustrate a semiconductor device in accordance with an embodiment of the present disclosure. FIG. 1A is a perspective view illustrating the semiconductor device, and FIG. 1B is a cross-sectional view of the semiconductor device taken along a line A-A′ shown in FIG. 1A.

Referring to FIGS. 1A and 1B, the semiconductor device in accordance with the embodiment of the present disclosure may include a substrate 100, a plurality of first interconnections 110 disposed over the substrate 100 and extending in a first direction, a plurality of second interconnections 120 disposed over the first interconnections 110 and extending in a second direction that intersects with the first direction (for example, substantially perpendicular to the first direction), and a plurality of memory cells MC disposed between the first interconnections 110 and the second interconnections 120 to overlap with the intersection areas between the first interconnections 110 and the second interconnections 120. Here, the first direction and the second direction may mean directions substantially parallel to the surface of the substrate 100. A direction substantially perpendicular to the surface of the substrate 100 may be, hereinafter, referred to as a vertical direction.

The substrate 100 may include a semiconductor material such as silicon. Also, a required predetermined lower structure (not shown) may be formed in the substrate 100. For example, an integrated circuit for driving a first interconnection 110 and/or a second interconnection 120 may be formed in the substrate 100.

The plurality of first interconnections 110 may be disposed to be spaced apart from each other in the second direction. The first interconnection 110 may include diverse conductive materials, for example, metals such as platinum (Pt), tungsten (W), aluminum (Al), copper (Cu), tantalum (Ta) and the like, metal nitrides such as titanium nitride (TiN), tantalum nitride (TaN) and the like, or a combination thereof. The first interconnection 110 may have a single-layer structure or a multi-layer structure.

The plurality of second interconnections 120 may be disposed to be spaced apart from each other in the first direction. The second interconnection 120 may include diverse conductive materials, for example, metals such as platinum (Pt), tungsten (W), aluminum (Al), copper (Cu), tantalum (Ta) and the like, metal nitrides such as titanium nitride (TiN), tantalum nitride (TaN) and the like, or a combination thereof. The second interconnection 120 may have a single-layer structure or a multi-layer structure. One among the first interconnection 110 and the second interconnection 120 may function as a word line, and the other may function as a bit line. Although this embodiment of the present disclosure illustrates a cross-point structure of one layer, a cross-point structure of two or more layers may be stacked in a vertical direction.

Each of the memory cells MC may include a memory unit MU, which is a portion where data are actually (for example, physically) stored, and a selector unit SU that controls access to the memory unit MU. For example, the memory cell MC may include a stacked structure of a first electrode layer 130, a selector layer 140, a second electrode layer 150, a memory layer 160, and a third electrode layer 170. In the illustrated embodiment, the selector unit SU may include the first electrode layer 130, the selector layer 140, and the second electrode layer 150. The memory unit MU may include the second electrode layer 150, the memory layer 160, and the third electrode layer 170. The second electrode layer 150 may be shared by the selector unit SU and the memory unit MU.

The first electrode layer 130 and the third electrode layer 170 may be disposed at both ends of the memory cell MC, that is, at the bottom and the top, respectively, and may function to transfer a voltage or current required for an operation of the memory cell MC. The second electrode layer 150 may function to electrically connect the selector layer 140 and the memory layer 160 to each other while physically separating them from each other. The first electrode layer 130, the second electrode layer 150, and/or the third electrode layer 170 may include diverse conductive materials, for example, metals such as platinum (Pt), tungsten (W), aluminum (Al), copper (Cu), tantalum (Ta), titanium (Ti) and the like, metal nitrides such as titanium nitride (TiN), tantalum nitride (TaN) and the like, or a combination thereof. Also, each of the first electrode layer 130, the second electrode layer 150, and the third electrode layer 170 may include a carbon electrode.

The memory layer 160 may function to store data in diverse ways. For example, the memory layer 160 may include a memory layer that stores different data by switching between different resistance states according to the voltage or current supplied through the upper and lower ends of the memory layer 160. The memory layer may have a single-layer structure or a multi-layer structure including diverse materials used in a Resistive Random Access Memory (RRAM), a Phase-change Random Access Memory (PRAM), a Ferroelectric Random Access Memory (FRAM), a Magnetic Random Access Memory (MRAM), and the like, for example, metal oxides such as transition metal oxides, perovskite-based materials and the like, phase-change materials such as chalcogenide-based materials, ferroelectric materials, ferromagnetic materials, and the like.

The memory layer 160 may include one or more of a lower layer, a free layer, a tunnel barrier layer, a fixed layer, a magnetic compensation layer, and a capping layer (not separately shown).

In some embodiments, the free layer may store different data by having a changeable magnetization direction, and the free layer may also be called a storage layer. The fixed layer may have a fixed magnetization direction and may be contrasted with the magnetization direction of the free layer, and the fixed layer may also be called a reference layer. The free layer and the fixed layer may have a single-layer structure or a multi-layer structure including a ferromagnetic material. For example, the free layer and the fixed layer may include an alloy mainly formed of iron (Fe), nickel (Ni) or cobalt (Co), such as an iron-platinum (Fe—Pt) alloy, an iron-palladium (Fe—Pd) alloy, a Co—Pd alloy, a Co—Pt alloy, a Fe—Ni—Pt alloy, a Co—Fe—Pt alloy, a Co—Ni—Pt alloy, a Fe—Pd alloy, a Co—Pd alloy, a Co—Pt alloy, a Fe—Ni—Pt alloy, a Co—Fe—Pt alloy, a Co—Ni—Pt alloy, a cobalt-iron-boron (Co—Fe—B) alloy, and the like, or may include a stacked structure such as Co/Pt or Co/Pd. The magnetization directions of the free layer and the fixed layer may be substantially perpendicular to the surfaces of the layers. In other words, the magnetization direction of the free layer may vary between a top-down direction and a bottom-up direction, and the magnetization direction of the fixed layer may be fixed to the top-down direction or the bottom-up direction. The magnetization direction of the free layer may be changed due to the spin transfer torque. The relative positions of the free layer and the fixed layer may vary diversely with a tunnel barrier layer interposed between them. For example, the fixed layer may be disposed below the tunnel barrier layer, and the free layer may be disposed over the tunnel barrier layer.

The tunnel barrier layer may enable tunneling of electrons between the free layer and the fixed layer during a write operation that changes the resistance state of the variable resistor element, thereby changing the magnetization direction of the free layer. The tunnel barrier layer may include a dielectric oxide, such as magnesium oxide (MgO), calcium oxide (CaO), strontium oxide (SrO), titanium oxide (TiO), vanadium oxide (VO), niobium monoxide (NbO), and the like. The free layer, the tunnel barrier layer, and the fixed layer may form an MTJ structure.

The selector layer 140 may be realized as a thin layer in the memory cell, and may have a function of preventing current leakage that may occur between the memory cells MC that share the first interconnection 110 or the second interconnection 120 while controlling the electrical access to one memory cell among a plurality of memory cells that are arrayed. To this end, the selector layer 140 may have the threshold switching characteristics of blocking off the current or holding current to hardly flow when the level of the voltage supplied to the upper and lower ends of the selector layer 140 is less than a predetermined threshold voltage level, and then letting the current flow rapidly (or freely) at a voltage level which is greater than or equal to the threshold voltage level. In other words, the selector layer 140 may be turned on at a voltage level which is greater than or equal to the threshold voltage level, and may be turned off at a voltage level which is less than the threshold voltage level. For example, the selector layer 140 may include a dielectric material into which a dopant is implanted. According to an embodiment of the present disclosure, the selector layer 140 may include an amorphous silicon layer that is doped with boron (B). According to yet another embodiment of the present disclosure, the selector layer 140 may be doped with arsenic (As) by performing an additional ion implantation process into the amorphous silicon layer that is doped with boron.

According to the embodiments of the present disclosure, the dopant doped into the amorphous silicon layer may be a Group-13 element of the periodic table instead of boron (B) and the amorphous silicon layer of the selector layer 140 may be doped with a Group-14element or a Group-15 element of the periodic table instead of arsenic (As).

An oxide layer 141 may be formed over the selector layer 140. The oxide layer 141 may serve as an additional passive layer on the surface of the selector layer 140, and the oxide layer 141 may be formed by, for example, an oxygen plasma treatment. This may also provide the selector layer 140 with a physically strong structure and allow long-term operation stability. The overall structure of the selector layer 140 may be uniformly formed through the oxygen plasma treatment, and a selector body ensuring a stable operation may be formed by controlling the change in the composition of the material. Even when a Group-15 element of the periodic table, such as arsenic (As), is ion-implanted after the formation of the oxide layer 141, the stability of the selector layer 140 may be maintained, and desired electrical characteristics may be secured while minimizing the change in the element composition.

Further, due to the oxygen plasma treatment, not only the oxide layer 141 may be formed over the selector layer 140, but also oxygen vacancies may be formed as oxygen is also implanted into the selector layer 140. When the oxygen vacancies are formed in the selector layer 140, they may serve as electron traps, capturing electrons in the current path and restricting their migration. This may suppress free migration of electrons, and as a result, leakage current I_{off} in the off-state may be significantly reduced. In other words, when the number of oxygen vacancies is increased, the migration of electrons in the conduction path may be further interrupted, and the flow of the current may be (almost, effectively) blocked in the off-state. Also, the electrical characteristics of the selector layer 140 including an amorphous silicon layer having a dopant may be precisely controlled by controlling the thickness of the oxide layer 141 according to the time taken for the oxygen plasma treatment.

Still further, the formation of the oxide layer 141 may affect the distribution and implantation depth of ions during the subsequent ion implantation process of a Group-15 element of the periodic table, such as arsenic (As), which may ultimately control the degree of activation of the dopant. These oxygen atoms may help the arsenic (As) ions to be distributed more uniformly by improving the characteristics at the interface between the oxide layer 141 and the selector layer 140.

Although FIGS. 1A and 1B show a memory cell MC having a stacked structure of the first electrode layer 130, the selector layer 140, the second electrode layer 150, the memory layer 160, and the third electrode layer 170, the concept and spirit of the present disclosure are not limited thereto, and the layer structure of the memory cell MC may be modified diversely. For example, at least one among the first electrode layer 130, the second electrode layer 150, and the third electrode layer 170 may be omitted. For example, the memory cell MC may include the selector layer 140, the first electrode layer 130 disposed below the selector layer 140, and the third electrode layer 170 disposed over the selector layer 140. For example, the first electrode layer 130 disposed below the selector layer 140 may include titanium nitride (TiN), and the third electrode layer 170 disposed over the selector layer 140 may include a carbon (C) electrode. Also, for example, the vertical positions of the selector layer 140 and the memory layer 160 may be switched. Also, for example, the memory cell MC may further include one or more layers (not shown) to improve the characteristics or the process.

In addition, an interlayer insulating layer 180 may be disposed to cover the lower interconnection layer 110 and fill the spaces between the vertically stacked structures of the memory cells MC. The interlayer insulating layer 180 may serve to electrically insulate adjacent memory cells and planarize the surface for subsequent processes.

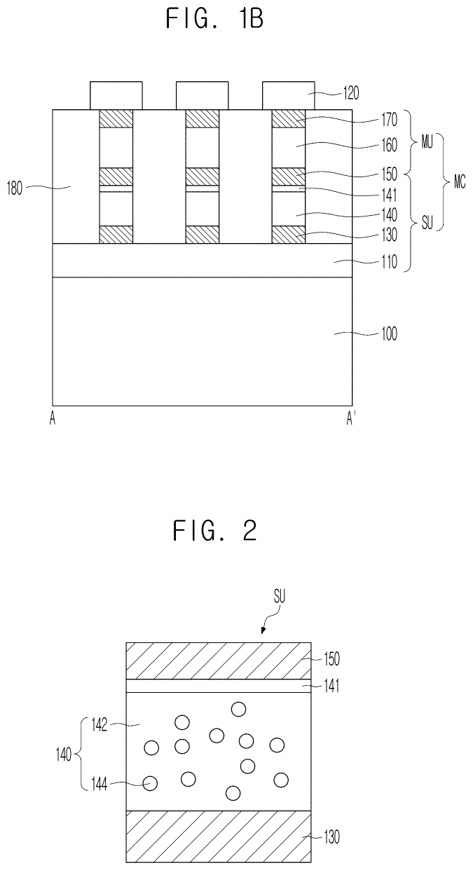

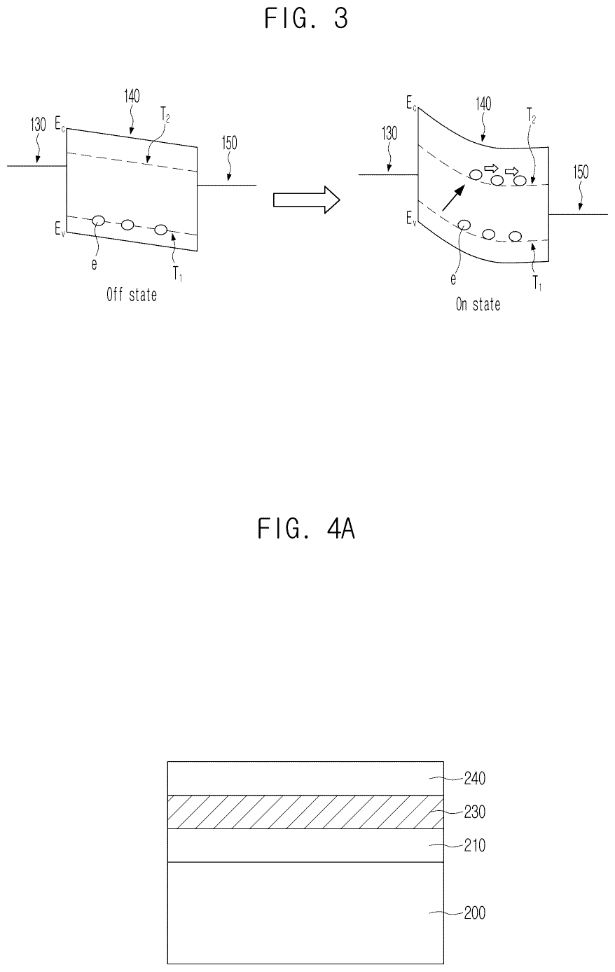

The selector unit SU including the selector layer 140 and the oxide layer 141 and the operation of the selector unit SU will be described in detail with reference to FIGS. 2 and 3 below.

FIG. 2 is a cross-sectional view illustrating a structure of the selector unit SU in accordance with the embodiment of the present disclosure.

Referring to FIG. 2, the selector unit SU may include the first electrode layer 130, the selector layer 140, the oxide layer 141, and the second electrode layer 150.

As described above, the first electrode layer 130 and the second electrode layer 150 may include diverse conductive materials, such as metals, metal nitrides, and the like. The first electrode layer 130 and the second electrode layer 150 may be formed of the same material and thus they may have the same work function. For example, each of the first electrode layer 130 and the second electrode layer 150 may include titanium nitride (TiN) having a work function of approximately 4.4 to 4.6 eV. However, the concept and spirit of the present disclosure are not limited thereto, and the first electrode layer 130 and the second electrode layer 150 may be formed of different materials to have different work functions.

The selector layer 140 may include a dielectric material layer 142, and a dopant 144 which is implanted into the dielectric material layer 142.

The dielectric material layer 142 may include a dielectric material having a relatively wide band gap, for example, a dielectric material having a band gap of approximately 5.0 eV or higher. For example, the dielectric material layer 142 may include a silicon-containing dielectric material such as silicon oxide, silicon nitride, silicon oxynitride and the like, a dielectric metal oxide, a dielectric metal nitride, or a combination thereof. For example, an oxide layer such as SiO₂ may be formed by mixing a source gas containing silicon (Si) and oxygen (O) through a method such as Chemical Vapor Deposition (CVD), Physical Vapor Deposition (PVD), or Atomic Layer Deposition (ALD). In the dielectric material layer 142, there may be a deep trap whose energy level is closer to the energy level of a valence band than to the energy level of a conduction band of the dielectric material layer 142. The dopant 144 may serve to create a shallow trap that provides a path for conductive carriers, such as electrons or holes, to migrate in the dielectric material layer 142. The shallow trap may have an energy level which is closer to the energy level of a conduction band than to the energy level of a valence band of the dielectric material layer 142.

The dopant doped into the selector layer 140 may include an N-type or P-type dopant and may be implanted by an ion implantation process. For example, when the dielectric material layer 142 contains silicon, the dopant 144 may include a Group-13 element, a Group-14 element and/or a Group-15 element of the periodic table having a valence that is different from the valence of silicon (Si). For example, the dopant 144 may include a Group-13 element of the periodic table, such as boron (B), aluminum (Al), gallium (Ga), or indium (In). For example, the dopant 144 may include a Group-14 element of the periodic table, such as carbon (C), silicon (Si), germanium (Ge), or tin (Sn), together with the Group-13 element of the periodic table. For example, the dopant 144 may include a Group-15 element of the periodic table, such as nitrogen (N), phosphorus (P), arsenic (As), or antimony (Sb), together with the Group-13 element of the periodic table. For example, the dopant 144 may include boron (B), and the dopant 144 may further include one or more among phosphorus (P) and arsenic (As), together with boron.

The dopant concentration and the ratio of amorphous silicon in the doped amorphous silicon layer may vary greatly according to the process conditions. The dopant concentration may be controlled by controlling the flow rate and hydraulic pressure of diborane (B₂H₆) and silane gas (SiₓH_{y}). For example, when the flow rate of diborane is increased, the dopant concentration may be increased, and conversely, when the flow rate of silane gas is increased, the ratio of amorphous silicon may be increased. When a doped amorphous silicon layer is generated by reacting diborane and silane gases under the temperature condition of approximately 300° C., the dopant 144 may have a concentration of approximately 10 to 30 wt % in the doped amorphous silicon layer, and the amorphous silicon may have a concentration of approximately 90 to 70 wt %. When the doped amorphous silicon layer is generated by reacting diborane and silane gases under the temperature condition of approximately 400° C., the diffusion of the dopant may become more active so that the dopant may be more easily doped into the amorphous silicon layer. Therefore, in this case, the dopant 144 may have a concentration of approximately 30 to 90 wt % in the doped amorphous silicon layer, and the amorphous silicon layer may have a concentration of approximately 70 to 10 wt %.

The oxide layer 141 may be disposed between the selector layer 140 and the second electrode layer 150 to serve as an additional passive layer on the surface of the selector layer 140 and improve the electrical characteristics thereof. The oxygen plasma treatment performed on the surface of the selector layer 140 may enhance the dielectric characteristics and increase the dielectric intensity by removing the impurities of the dielectric material layer 142 and improving the surface condition of the dielectric material layer 142. The oxygen plasma treatment may also increase the activation and stability of the dopant 144, and increase the capability to stably maintain the dopant at the interface with the oxide layer.

The operation of the selector unit SU is described below with reference to FIG. 3.

FIG. 3 illustrates an operation of the selector unit SU shown in FIG. 2. Referring to FIG. 3, in the off-state where no voltage is applied to the selector unit SU, conductive carriers, for example, electrons (e), may be trapped in the deep trap T₁ of the selector layer 140.

FIG. 3 illustrates an energy band diagram for electrons in semiconductor in which E_{c} represents the energy level at the bottom of the conduction band and Eᵥ represents the energy level at the top of the valence band. When a voltage whose level is greater than or equal to the threshold voltage level is applied to the selector unit SU in the off-state through the first electrode layer 130 and the third electrode layer 150, an on-state in which the current flows through the selector unit SU may be realized. To be specific, when a voltage whose level is greater than or equal to the threshold voltage level is applied to the selector unit SU, the conductive carriers (e) trapped in the deep trap T₁ may jump to the shallow trap T₂ by thermal emission or tunneling, and a conduction path coupling the first electrode layer 130 and the third electrode layer 150 may be created as the conductive carriers (e) migrate through the shallow trap T₂.

When the voltage applied to the selector unit SU of the on-state is decreased, the number of the conductive carriers migrating from the deep trap T₁ to the shallow trap T₂ may also be decreased to turn off the selector unit SU again.

In this way, the selector unit SU may be turned on or off.

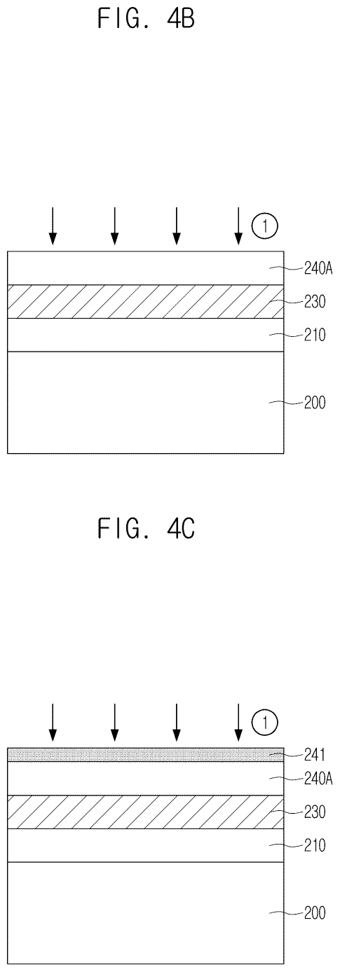

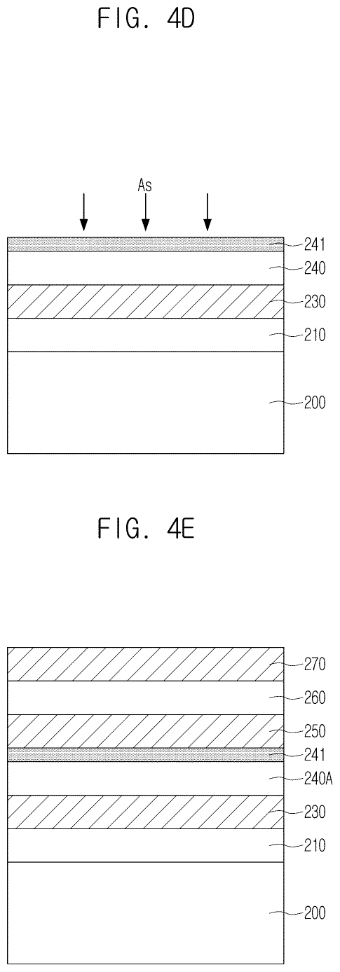

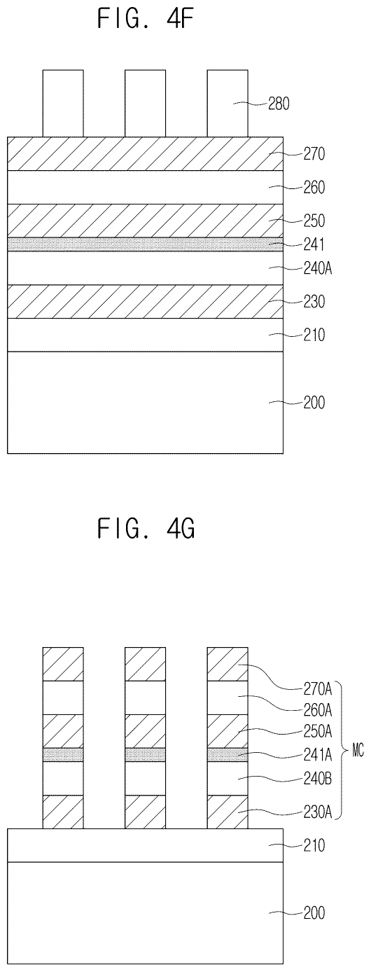

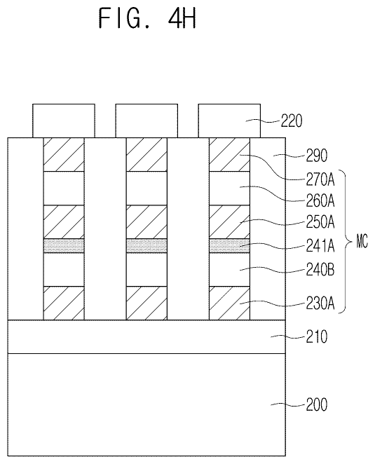

FIGS. 4A to 4H are cross-sectional views illustrating a semiconductor device and a method for fabricating the same in accordance with an embodiment of the present disclosure.

First, the method for fabricating a semiconductor device is described.

Referring to FIG. 4A, a substrate 200 having a predetermined lower structure formed therein may be provided. The substrate 200 may include diverse required circuits. A first interconnection 210 may be formed over the substrate 200. The first interconnection 210 may be formed by forming a gap-fill layer (not shown) having a trench for forming the first interconnection 210 over the predetermined structure, and depositing a conductive layer for forming the first interconnection 210 in the trench. The first interconnection 210 may include diverse conductive materials, for example, metals such as platinum (Pt), tungsten (W), aluminum (Al), copper (Cu), tantalum (Ta) and the like, metal nitrides such as titanium nitride (TiN), tantalum nitride (TaN) and the like, or a combination thereof. The first interconnection 210 may have a single-layer structure or a multi-layer structure.

Subsequently, a first electrode layer 230 may be formed over the first interconnection 210. The first electrode layer 230 may be implemented as a TiN thin layer.

Subsequently, an amorphous silicon layer that is doped with a dopant may be formed as an initial selector layer 240 over the first electrode layer 230. Here, the method for forming the amorphous silicon layer that is doped with a dopant may be implemented as a method of depositing an amorphous silicon layer that is doped with a first dopant. The first dopant may be a Group-13 element of the periodic table, such as boron (B), aluminum (Al), gallium (Ga), or indium (In). For example, the amorphous silicon layer may include boron (B) as the first dopant.

The amorphous silicon layer having the first dopant may be formed by a Low-Pressure Chemical Vapor Deposition (LPCVD) process using a first dopant-containing catalyst and a silicon source gas. For example, the amorphous silicon layer having the first dopant may be formed by a Low-Pressure Chemical Vapor Deposition (LPCVD) process using silane gas (SiₓH_{y}) (for example, silane (SiH₄) and diborane (B₂H₆)). The low-pressure chemical vapor deposition (LPCVD) process may provide a uniform thin layer and a low defect rate, thereby improving the performance of the semiconductor device.

When boron (B) is applied as the first dopant, the boron-containing catalyst may be selected among trimethyl borate (B(Ome)₃), boron trichloride (BCl₃), boron tribromide (BBr₃), boron dibromide (BBr₂), boron trifluoride (BF₃), or diborane (B₂H₆). In the case of boron (B)-containing catalysts that do not contain hydrogen, the catalyst may be supplied together with hydrogen (H₂).

Subsequently, referring to FIGS. 4B and 4C, an oxide layer 241 may be formed over the initial selector layer 240 by performing the oxygen plasma treatment onto the initial selector layer 240 including the amorphous silicon layer that is doped with the dopant and oxidizing at least a portion of the surface of the initial selector layer 240 (see arrow \textcircled{1}).

The oxygen plasma treatment may be performed at a temperature of approximately 250 to 350° C., and in some instances more favorably at a temperature of approximately 280 to 320° C. This temperature range of the oxygen plasma treatment may be selected as an optimal temperature range that may not only control the oxidation rate by providing an appropriate energy to cause an oxidation reaction to occur smoothly on the surface of the initial selector layer 240, but also prevent the layer from being destroyed or being formed irregularly (e.g., non-uniformly, patchily) due to excessive oxidation while maintaining the uniformity of the oxide layer 241.

Further, the oxygen plasma treatment may be performed for approximately 1 to 150 seconds, and in an embodiment, optimally for approximately 60 to 120 seconds. There is no significant difference in the oxidation intensity of the initial selector layer 240 according to the time taken for the oxygen plasma treatment, but in instances in which the oxygen plasma treatment is performed for too long, the oxide layer 241 may be excessively formed, which may have a negative influence on the electrical characteristics, and the high energy state of the plasma may damage the surface of the selector layer 240A. On the other hand, in instances in which the treatment time not sufficient (for example, the treatment time is too short), the oxide layer 241 may not be sufficiently formed, and thus electrical dielectric characteristics or stability may not be secured.

The oxygen plasma treatment may implant activated oxygen atoms or ions into the initial selector layer 240 to interact with the surface of the initial selector layer 240. In this process, the oxygen atoms may chemically react with the material of the initial selector layer 240 to form the oxide layer 241 of an oxide, and the oxygen may also be absorbed into the initial selector layer 240. As a result, since silicon (Si) and/or boron (B) of the initial selector layer 240 are/is oxidized to form the oxide layer 241, the atomic percent at % of oxygen (O) may be increased while the atomic percent at % of silicon (Si) and/or boron (B) of the initial selector layer 240 is decreased. Accordingly, the oxide layer 241 may include, for example, silicon dioxide (SiO₂), and/or boron trioxide (B₂O₃).

An oxidation reaction may occur on the surface of the initial selector layer 240 by applying the oxygen plasma treatment to cover the surface of the initial selector layer 240 with an oxide. This may have a significant influence on the overall electrical characteristics and physical stability of the formed selector layer (240A in FIG. 4E), and the oxidized surface may provide higher dielectric characteristics and durability to the selector layer 240A. Also, the overall structure of the initial selector layer 240 may be uniformly formed through the oxygen plasma treatment, and the composition change of the material may be controlled. Therefore, a selector body with a stable operation may be formed.

Due to the oxygen plasma treatment, not only the oxide layer 241 may be formed over the initial selector layer 240, but also oxygen vacancies may be formed by implanting oxygen into the initial selector layer 240. When the oxygen vacancies are formed in the initial selector layer 240, they may serve as electron traps to capture electrons in the current path and restrict the migration of the electrons. This may suppress the free migration of electrons, and as a result, leakage current I_{off} in the off-state may be significantly reduced. In other words, when the number of oxygen vacancies is increased, electron migration in the conduction path may be further interrupted, and the flow of current may be almost blocked in the off-state. Also, the electrical characteristics of the initial selector layer 240 including the amorphous silicon layer having a dopant may be precisely controlled by controlling the thickness of the initial selector layer 240 according to the time taken for the oxygen plasma treatment.

The oxide layer 241 after the oxygen plasma treatment may preferably have a thickness of approximately 10 to 30 Å, and in particular embodiments, optimally, a thickness of approximately 15 to 25 Å. This is because in instances in which the oxide layer 241 is too thin, the oxide layer 241 may have insufficient dielectric characteristics, and in instances in which the oxide layer 241 is too thick, the thick oxide layer 241 may negatively affect the electrical characteristics of the selector layer 240A. Therefore, the thickness range of the oxide layer 241 may be an optimal thickness that may maintain the balance between the dielectric characteristics and the conductive characteristics while effectively controlling the conduction path of the selector layer 240A.

Referring to FIG. 4D, the selector layer 240A may be formed of an amorphous silicon layer including a first dopant and/or a second dopant by implanting the first dopant and/or the second dopant into the initial selector layer 240. The selector layer 240A may have a thickness of approximately 50 to 150 Å. In one embodiment, the selector layer 240A may have a thickness of approximately 80 to 120 Å. In another embodiment, the selector layer 240A may have a thickness of approximately 100 Å. In instances in which the selector layer 240A is too thin (or falls below a particular minimum thinness), the selector layer 240A may not trap sufficient charges, which may lower the resistance in the off-state and increase the leakage current. In instances in which the selector layer 240A is too thick (or exceeds a particular (maximum) thickness), the conduction path may become too long in the on-state, which may decrease the current flow. Also, in instances in which the selector layer 240A is too thin, the switching may become unstable, which may result in severe resistance fluctuations. In instances in which the selector layer 240A is too thick, the switching rate may be decreased. With a thickness of approximately 50 to 150 Å, the selector layer 240A may optimize the current flow and effectively control the resistance by balancing the formations of the charge traps and the conduction paths, and maintain a fast switching rate while ensuring a stable switching operation.

A second dopant, for example, arsenic (As), may be ion-implanted into the amorphous silicon layer having the first dopant. The second dopant may include a Group-15 element of the periodic table, for example, nitrogen (N), phosphorus (P), or antimony (Sb) in addition to arsenic (As). In an embodiment, the first dopant may optimally include boron (B), and the second dopant may include at least one selected from the group including phosphorus (P) and arsenic (As). The ion-implantation of the second dopant may be performed in a direction substantially perpendicular to the surface of the substrate 200, and a tilted ion-implantation may also be performed. Also, the ion-implantation may be performed repeatedly several times. Electrical characteristics may be manipulated (for example, engineered, developed) in the semiconductor device which is fabricated by ion-implanting the second dopant, such as arsenic (As), into the amorphous silicon layer. The characteristics of the semiconductor device may be appropriately changed by changing the concentration of the ion-implanted second dopant. By adjusting the implanted energy and angle, the concentration of the dopant can be capably controlled as well as implantation of the dopant to a desired depth. The concentration of the dopant may be controlled according to the implantation conditions, such as energy, implantation time, and ion implantation rate, and for example, the concentration of the dopant may be controlled from approximately 10% to 50% according to the implantation conditions. A high concentration of the dopant may contribute to forming a current path more easily, but on the other hand, the higher concentration of the dopant may also increase the leakage current. Therefore, it is desirable to control the concentration of the dopant in the above range. The ion implantation process may be performed repeatedly several times to evenly distribute the dopant. The repetition of this process may ensure that the conduction path is formed more stably in the amorphous silicon layer.

The dopant ions implanted during the ion implantation process may impact the crystal structure in the silicon layer due to the high energy. In particular, in instances in which a Group-15 element such as arsenic (As) or phosphorus (P) is implanted as a dopant into the amorphous silicon layer, a local re-crystallization phenomenon may occur at the implanted location. This re-crystallization may facilitate forming the conduction path more easily. This may improve the conductive characteristics of the selector in the on-state by mainly activating the conduction path more. The ion implantation process may control the electrical characteristics of the semiconductor device by implanting the second dopant into the amorphous silicon layer, and induce formation of the conduction path of the implanted dopant. This may allow the selector to have the desired current-voltage characteristics, and make it easier to form the conduction path.

The ion implantation process of the second dopant described with reference to FIG. 4D may be omitted in the process of forming the selector pattern 240B according to the embodiment of the present disclosure. In other words, a semiconductor device may be fabricated with suitability for a particular purpose and characteristic only with the amorphous silicon layer into which the first dopant is implanted as the selector pattern 240B. However, when the second dopant is additionally implanted, the conduction path may be formed more easily, and thus the electrical characteristics of the selector may be enhanced.

A heat treatment may be performed on the selector layer 240A at a temperature equal to or lower than a temperature where the amorphous silicon layer is crystallized. This heat treatment may be carried out after the oxygen plasma treatment and/or after the dopant implantation process, to stabilize the electrical and structural characteristics of the selector layer 240A. Performing the heat treatment at or below the crystallization temperature helps maintain the amorphous state of the silicon layer, which is essential to preserve the threshold switching characteristics of the selector. If the silicon layer crystallizes, grain boundaries or filamentary conduction paths may form, potentially degrading the off-state performance and increasing leakage current. Additionally, the heat treatment may serve to reduce plasma-induced damage, activate implanted dopants, and improve the uniformity and durability of the selector layer 240A.

The heat treatment may be performed at a temperature in the range of approximately 250° C. to 400° C. for a duration of about 30 to 300 seconds, depending on the specific process conditions and materials used. These conditions are selected to avoid crystallization of the amorphous silicon while still providing sufficient thermal energy to enhance the stability of the device. Other conditions, such as the ambient atmosphere (e.g., nitrogen or argon), may be optimized to prevent unwanted oxidation or contamination during the process.

Subsequently, referring to FIG. 4E, a second electrode layer 250, a memory layer 260, and a third electrode layer 270 may be formed over the oxide layer 241. The second electrode layer 250 and the third electrode layer 270 may be formed by a method of depositing a conductive material. The second electrode layer 250 may be selected to be (for example, materials may be selected to form) a single TiN thin layer, and the single TiN thin layer may be implemented by stacking a carbon (C) thin layer and a TiN layer. Here, the carbon (C) thin layer may be formed at the interface between the oxide layer 241 and the TiN layer, thereby improving the interface characteristics between the electrodes. Also, a silicon nitride (SiN) thin layer may be formed between the first electrode layer 230 and the selector layer 240A, and a carbon (C) thin layer may be formed between the selector layer 240A and the second electrode layer 250.

The third electrode layer 270 may be formed over the second electrode layer 250 and the memory layer 260, and may be generally formed of a material that sustains a high-temperature heat treatment and has excellent conductivity. The third electrode layer 270 may be formed by performing a metal deposition process or a sputtering process. To be specific, the third electrode layer 270 may be formed by depositing a conductive metal layer such as TiN, tungsten (W), copper (Cu), or aluminum (Al).

In the process of forming the third electrode layer 270, it is important to maintain high deposition uniformity and conductivity, and the metal layer may be formed to have a desired thickness through a process such as plasma sputtering or Chemical Vapor Deposition (CVD). After the third electrode layer 270 is formed, an additional heat treatment or a patterning process may be performed to provide optimal electrical connection characteristics in the semiconductor device.

Referring to FIG. 4F, a hard mask layer 280 may be formed over the third electrode layer 270. The hard mask layer 280 may be formed by forming a material layer for the hard mask layer 280 and a photoresist pattern (not shown) and etching the material layer for the hard mask layer 280 with the photoresist pattern used as an etching barrier. The hard mask layer 280 may function as an etching barrier during the etching process for forming a memory cell MC. The hard mask layer 280 may include diverse materials capable of securing an etching selectivity with respect to the memory cell MC. For example, the material layer for the hard mask layer 280 may have a single layer structure or a multi-layer structure including diverse dielectric materials such as silicon oxide, silicon nitride, silicon oxide nitride and the like.

Referring to FIG. 4G, a memory cell MC including a third electrode pattern 270A, a variable resistance pattern 260A, a second electrode pattern 250A, an oxide layer pattern 241A, a selector pattern 240B, and a first electrode pattern 230A may be formed by using the hard mask layer 280 as an etching barrier and etching the third electrode layer 270, the memory layer 260, the second electrode layer 250, the oxide layer 241, the selector layer 240A, and the first electrode layer 230.

According to the embodiment of the present disclosure, the hard mask layer 280 may be removed in the process of etching the memory cell MC. Alternatively, according to another embodiment of the present disclosure, part or all of the hard mask layer 280 may remain and may be removed in a planarization process, which may be performed subsequently.

Referring to FIG. 4H, an inter-layer dielectric layer 290 may be formed between the memory cells MC. The inter-layer dielectric layer 290 may be formed to have a thickness that sufficiently fills the space between the memory cells MC and covers the upper portion. The inter-layer dielectric layer 290 may have a single-layer structure or a multi-layer structure including diverse dielectric materials, such as silicon oxide, silicon nitride, or a combination thereof.

Subsequently, a planarization process, such as a Chemical Mechanical Polishing (CMP) process, may be performed on the inter-layer dielectric layer 290 until the upper surface of the memory cell MC is exposed. The hard mask layer 280 may not be completely removed but remains in the aforementioned memory cell MC etching process, however, the hard mask layer 280 may also be removed together as the planarization process may be performed until the upper surface of the memory cell MC is exposed in the planarization process.

Subsequently, a plurality of second interconnections 220 extending in the second direction that intersects with the first direction, for example, the second direction of FIG. 1A, while being coupled to the upper surface of the memory cell MC, may be formed over the memory cell MC and the inter-layer dielectric layer 290. The second interconnections 220 may be formed by a process of depositing a conductive material and patterning the conductive material, and the space between the second interconnections 220 may be filled with a dielectric material (not shown).

The semiconductor device in accordance with the embodiment of the present disclosure, as illustrated in FIG. 4H, may be fabricated by the process described above.

Referring back to FIG. 4H, the semiconductor device in accordance with the embodiment of the present disclosure may have a structure in which the oxide layer pattern 241A is disposed between the selector pattern 240B and the second electrode pattern 250A. In other words, the semiconductor device in accordance with the embodiment of the present disclosure may include the substrate 200, and the first interconnection 210, the first electrode pattern 230A, the selector pattern 240B, the oxide layer pattern 241A, the second electrode pattern 250A, the variable resistance pattern 260A, the third electrode pattern 270A, and the second interconnection 220 that are sequentially formed over the substrate 200.

The process structure of FIG. 4H may be substantially the same as the process structure of FIG. 1A described above. In other words, the substrate 200, the first interconnection 210, the first electrode pattern 230A, the selector pattern 240B, the oxide layer pattern 241A, the second electrode pattern 250A, the variable resistance pattern 260A, the third electrode pattern 270A, and the second interconnection 220 may respectively correspond to the substrate 100, the first interconnection 110, the first electrode layer 130, the selector layer 140, the oxide layer 141, the second electrode layer 150, the memory layer 160, the third electrode layer 170, and the second interconnection 120 shown in FIG. 1A. Therefore, detailed description on the portion corresponding to the process structure of FIG. 1A described above will be omitted herein.

According to the embodiment of the present disclosure, the semiconductor device and a method for fabricating the same may have improved selector characteristics by forming an oxide layer over the selector layer.

While the present disclosure has been described with respect to the specific embodiments, it will be apparent to those skilled in the art that diverse changes and modifications may be made without departing from the spirit and scope of the disclosure as defined in the following claims.

What is claimed is:

1. A semiconductor device, comprising:
a plurality of memory cells,
wherein each of the memory cells includes
a memory layer;
a selector layer configured to select the memory layer, wherein the selector layer includes an amorphous silicon layer having a dopant including a Group-13 element and a Group-15 element of a periodic table; and
an oxide layer disposed over the selector layer and formed by oxidizing at least a portion of the selector layer.

2. The semiconductor device of claim 1, wherein the dopant includes boron (B) and at least one among phosphorus (P) and arsenic (As).

3. The semiconductor device of claim 1, wherein the dopant includes arsenic (As) and boron (B).

4. The semiconductor device of claim 1, wherein the dopant has a concentration of 10 to 30 wt % in the amorphous silicon layer having the dopant.

5. The semiconductor device of claim 1, wherein the dopant has a concentration of 30 to 90 wt % in the amorphous silicon layer having the dopant.

6. The semiconductor device of claim 1, wherein each of the memory cells further includes
a first electrode layer disposed below the selector layer and
a second electrode layer disposed over the selector layer.

7. The semiconductor device of claim 6, wherein the first electrode layer and the second electrode layer include a titanium nitride (TiN) thin layer.

8. The semiconductor device of claim 6, further comprising:
a silicon nitride (SiN) thin layer between the first electrode layer and the selector layer, and
a carbon (C) thin layer between the selector layer and the second electrode layer.

9. The semiconductor device of claim 1, wherein the oxide layer has a thickness of 10 to 30 Å.

10. The semiconductor device of claim 1, wherein the selector layer has a thickness of 50 to 150 Å.

11. The semiconductor device of claim 1, wherein the selector layer is disposed over or below the memory layer.

12. A method for fabricating a semiconductor device including a selector layer in a memory cell among a plurality of arrayed memory cells to control electrical access to the memory cell, comprising:
forming, over a substrate, an amorphous silicon layer having at least one dopant as the selector layer;
oxidizing at least a portion of the selector layer, by performing an oxygen plasma treatment, to form an oxide layer over the selector layer; and
performing a heat treatment at a temperature less than or equal to a temperature where the amorphous silicon layer is crystallized.

13. The method of claim 12, wherein the oxygen plasma treatment is performed at a temperature of 250 to 350°C.

14. The method of claim 12, wherein the oxygen plasma treatment is performed for 1 to 150 seconds.

15. The method of claim 12, wherein the forming of the amorphous silicon layer having the at least one dopant includes:
depositing the amorphous silicon layer that is doped with a first dopant.

16. The method of claim 15, wherein the depositing of the amorphous silicon layer that is doped with the first dopant is performed by a Low-Pressure Chemical Vapor Deposition (LPCVD) process using silane (SiH₄) and diborane (B₂H₆).

17. The method of claim 12, wherein the dopant has a concentration of 10 to 30 wt % in the amorphous silicon layer having the dopant.

18. The method of claim 12, wherein the dopant has a concentration of 30 to 90 wt % in the amorphous silicon layer having the dopant.

19. The method of claim 12, further comprising:
forming an electrode layer over the selector layer.

20. The method of claim 12, wherein the forming of the amorphous silicon layer having the dopant includes:
depositing an amorphous silicon layer that is doped with a first dopant; and
ion-implanting a second dopant into the amorphous silicon layer that is doped with the first dopant.

21. The method of claim 20, wherein the first dopant includes a Group-13 element of a periodic table, and
the second dopant includes a Group-15 element of the periodic table.

22. The method of claim 20, wherein the first dopant includes boron (B), and
the second dopant includes at least one selected from a group including phosphorus (P) and arsenic (As).

23. The method of claim 12, wherein the heat treatment is performed at a temperature of 400° C. or lower.
